(19) United States
(12) Patent Application Publication
(10) Pub. No.: US 2007/0087464 A1
(43) Pub. Date: Apr. 19, 2007

(54) Method for producing etched holes and/or etched trenches as well as a diaphragm sensor unit

(76) Inventor: Joachim Rudhard, Leinfelden-Echterdingen (DE)

Correspondence Address: KENYON & KENYON LLP, ONE BROADWAY, NEW YORK, NY, 10004, US

(21) Appl. No.: 10/571,246

(22) PCT Filed: Jul. 7, 2004
(86) PCT No.: PCT/DE04/01449

§ 371 Date: Dec. 5, 2006

(30) Foreign Application Priority Data
Sep. 12, 2003 (DE) 103 42 155.6

(51) Int. Cl. H01L 21/00; H01L 29/84; H01L 21/76

(52) U.S. Cl. 438/50; 438/424; 257/419

(57) ABSTRACT

A method for producing etched holes and/or etched trenches of components based on silicon and/or a layered silicon/insulator structure. A germanium-containing layer and/or a germanium layer is provided at the point in the etching direction at which or in whose surroundings an etching procedure is to be completed. Germanium and/or germanium compounds are detected during the etching procedure and the etching procedure is controlled, in particular interrupted, as a function of the detection of germanium and/or germanium compounds. In addition, a diaphragm sensor unit is provided, in whose layered structure a germanium and/or germanium-containing layer is provided.

### BACKGROUND INFORMATION

In semiconductor technology, there are an array of applications in which etched holes and/or etched trenches must be produced comparatively deep into a substrate, e.g., into a wafer or possibly completely through the substrate. In particular, producing a through hole in a wafer, for example, is difficult in most processes.

A method in which a silicon wafer is etched from the back, at the points at which a continuous trench or a through hole is to be produced, up to a predefined non-critical depth with the aid of a KOH etching process, for example, is known. Subsequently, the resulting etched structures are filled up with a resist, e.g., photoresist. Furthermore, the continuous trenches or the through hole may be etched into the wafer from the front without problems, the resist being used as an etch stop simultaneously preventing etching medium from being able to reach a particular region of the process system and/or the wafer clamping device on the back of the wafer through the wafer, the process thus being stopped and/or the particular units being contaminated.

Such a procedure is comparatively complex, however. This is because, as the wafer back is structured, the front must be protected from damage simultaneously. In addition, a separate resist application step is necessary for filling up the depressions arising on the back.

An object of the present invention is to make the production of etched holes and/or etched trenches in a substrate comparatively simpler and more defined.

### SUMMARY OF THE INVENTION

The present invention is first directed to a method for producing etched holes and/or etched trenches of components based on silicon and/or a layered silicon/insulator structure. A core of the present invention is that a germanium-containing layer and/or a germanium layer is provided at the point at which or in whose surroundings an an etching procedure in the silicon and/or an insulator is to be completed; detection for germanium and/or germanium compounds is performed during the etching procedure, and the etching procedure is controlled, in particular interrupted, as a function of the detection of germanium and/or germanium compounds. This procedure is based on the recognition that germanium and/or germanium compounds may be comparatively easily detected in an etching procedure in relation to etching products during the etching of silicon or insulators typically used in the semiconductor field. A mass spectrometer or an optical emission spectrometer may be used to detect germanium or germanium compounds, e.g., to analyze an etching plasma.

For example, in an etching plasma based on fluorine chemistry, the occurrence of a GeFₓ line is monitored using an optical emission spectrometer, in order to be able to determine that a germanium layer and/or a germanium-containing layer has been reached. The occurrence of a line of this type in the spectrum may be used as a “stop criterion” for the etching process, specifically when etched trenches or etched holes are to be introduced up to the corresponding germanium and/or germanium-containing layer in a wafer, for example.

In a particularly preferred embodiment of the method according to the present invention, the germanium and/or germanium-containing layer is applied to the back of the silicon wafer. Through this measure, an etched trench or a hole may be etched through the entire wafer using typical plasma etching processes; complete etching through the wafer may be determined easily by the detection of germanium etching products. At this moment, the etching procedure is preferably stopped, so that there is still not a continuous passage to the back of the wafer. Rather, the germanium layer represents a protective barrier, so that no etching medium may reach a wafer clamping device on the back of the wafer, for example, and/or support of the wafer using a vacuum chuck is still possible, for example.

Preferably, after completing the etching procedure up to the germanium and/or germanium-containing layer, this layer is completely removed. A germanium layer or a germanium-containing layer may be removed selectively from silicon and/or typical insulators used in semiconductor technology, for example, with the aid of hydrogen peroxide or etching solutions containing hydrogen peroxide.

A germanium and/or germanium-containing layer, e.g., a germanium-containing silicon layer (SiGe) may be deposited using CVD (chemical vapor deposition) or PECVD (plasma-enhanced chemical vapor deposition) if this is compatible with the overall process, the preceding process steps in particular. A germanium or germanium-containing layer may also be sputtered on, which is possible at comparatively low temperatures. In the event of layer production using sputtering, there is also the possibility of combining a germanium and/or germanium-containing layer with further layers into an advantageous layer sandwich. For example, the germanium and/or germanium-containing layer may be provided with a metal cover layer, such as tungsten-titanium, for example. This has advantages in regard to contamination prevention.

A germanium and/or germanium-containing layer applied to the back of a wafer may, for example, also advantageously be used for breaking up the wafer into electronic components by producing trenches which completely penetrate up to the germanium layer in the wafer and removing the germanium layer in a following step, through which individual components corresponding to the etched trenches arise, since they are no longer held together by the rear germanium and/or germanium-containing layer after it is removed.

In an additionally preferred embodiment of the present invention, the germanium and/or germanium-containing layer is buried in a layered structure. In this structure, the germanium and/or germanium-containing layer may be used in a controlled way as the “etch stop” layer, in that germanium and/or germanium compounds are detected during etching procedures in a layer lying above and/or multiple layers lying above (which do not contain germanium). In this way, “trench etching processes” or etching processes for producing a cavity may be performed in a more defined way, for example.

These advantages may be achieved in particular in a diaphragm sensor unit having a substrate made of silicon or a layered silicon/insulator structure, which includes a flat diaphragm to implement a sensor element structure for a sensor if, according to the present invention, a germanium and/or germanium-containing layer is provided in the layered structure.

A buried germanium and/or germanium-containing layer in the layered structure may simultaneously be used as a component functional layer. For example, this layer may be used as a diaphragm which arises in one or more etching processes by removing adjoining material, such as silicon or silicon-containing oxides. Such a procedure is reliably possible through the comparatively exact detectability of reaching the germanium and/or germanium-containing layer.

In principle, a germanium and/or germanium-containing layer may be used to control a lateral and/or vertical etching process on the substrate.

### BRIEF DESCRIPTION OF THE DRAWINGS

FIGS. 1 through 6 show schematic sectional representations at six process stages of a process sequence, simplified to important steps, on the basis of the example of producing a piezoresistive force transducer in SOI (silicon on insulator) technology.

### DETAILED DESCRIPTION

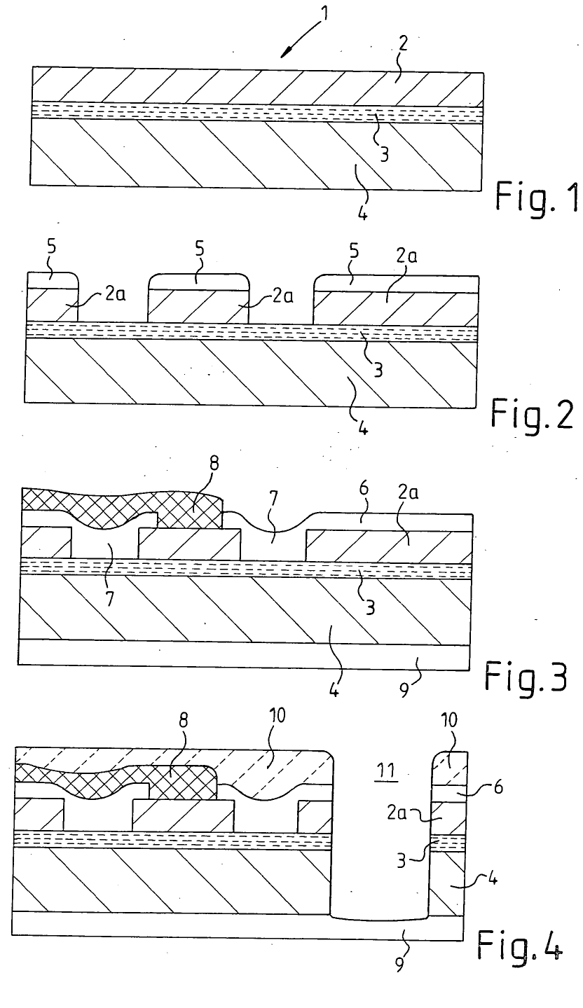

An SOI wafer 1 is shown in section in FIG. 1. SOI wafer 1 includes functional silicon 2 and an SOI oxide layer 3 on bulk silicon 4.

In FIG. 2, the layered structure after structuring functional silicon 2 into subregions 2a with the aid of a photoresist mask 5 using an anisotropic etching process is shown. Functional layer 2 is trenched (etched through) up to SOI oxide layer 3.

FIG. 3 shows a process stage according to the following steps:

Resist mass 4 was removed. “Trenched” regions 7 were filled up between functional silicon regions 2a using a filler oxide 6, and filler oxide 6 was opened again in contact regions 8 via a further mask/photolithography step. In two subsequent sputtering steps, the metal plating for contacts 8 on the front and a germanium layer 9 on the back of wafer 1 were sputtered on. The contact plane was structured in a metal dry etching process, for example, via a further mask/photolithography process. Structured contact metal 8 remained as a result of this process series.

The sectional representation in FIG. 4 resulted according to the following further process steps:

A PECVD protective oxide layer 10 was applied to the layered structure and the regions at which a “trench” (etched trench) are to be etched through wafer 1 were defined via a photolithography process step. Typical “trenching processes” may be used for etching a trench 11. In the present example, trench 11 was etched through the layered structure of thin protective oxide 10, filler oxide 6, functional silicon 2a, thin SOI oxide 3, and thick bulk silicon 4. A “deep trench” 11 through wafer 1 remains, which ends at germanium layer 9, however, because the etching process was interrupted there due to the detection of the germanium layer in the etching process.

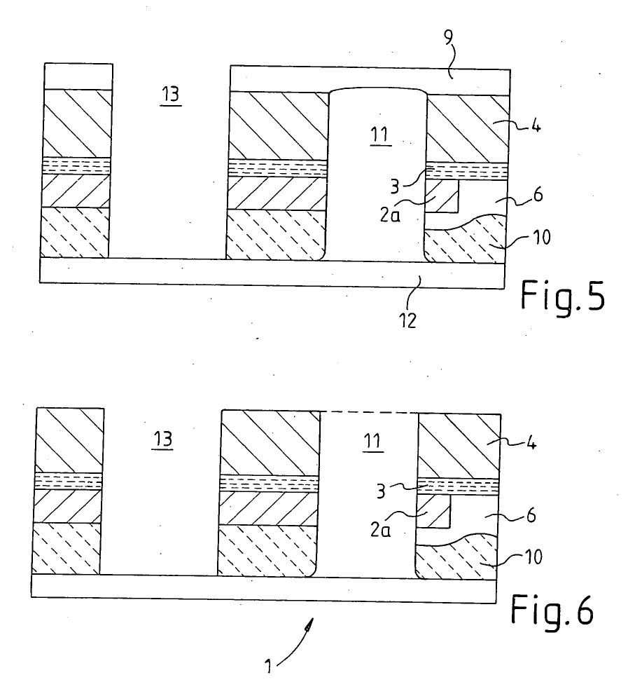

The wafer, which is fixed on “blue tape” 12 for sawing, is shown with an already sawed sawing path 13 in FIG. 5. For this purpose, wafer 1 was fixed on the “blue tape” by its front.

FIG. 6 shows the process stage with germanium layer 9 removed. For this purpose, for example, a hydrogen peroxide solution like a spray developer may be used, for example. After the germanium layer is removed, the wafer may be separated into the individual components by removing “blue tape” 12.

1-8. (canceled)

9. A method for producing at least one of (a) etched holes and (b) etched trenches of a component based on one of (c) silicon and (d) a layered silicon/insulator structure, the method comprising:
providing at least one of a germanium-containing layer and a germanium layer at a point at which or in whose surroundings an etching procedure is to be completed;
detecting at least one of germanium and germanium compounds during the etching procedure; and
controlling the etching procedure as a function of the detection.

10. The method according to claim 9, wherein the controlling includes interrupting the etching procedure.

11. The method according to claim 9, wherein at least one of the germanium and germanium-containing layer is buried in a layered structure.

12. The method according to claim 9, further comprising applying at least one of the germanium and germanium-containing layer to a back of a silicon wafer.

13. The method according to claim 9, further comprising removing at least one of the germanium and germanium-containing layer after completion of a etching procedure up to at least one of the germanium and germanium-containing layer.

14. The method according to claim 9, wherein at least one of the germanium and germanium-containing layer is simultaneously used as a component functional layer.

15. The method according to claim 9, wherein the at least one of germanium and germanium compounds is detected using one of optical emission spectroscopy and mass spectroscopy.

16. A diaphragm sensor unit comprising:
a substrate made of one of silicon and a layered silicon/insulator structure; and
a flat diaphragm for implementing a sensor element structure for a sensor,
wherein at least one of a germanium and germanium-containing layer is situated in the layered structure.

17. The diaphragm sensor unit according to claim 16, wherein the flat diaphragm contains germanium.

18. The diaphragm sensor unit according to claim 16, wherein the flat diaphragm is made entirely of germanium.
